(19) United States
(12) Patent Application Publication
(10) Pub. No.: US 2007/0001290 A1
(43) Pub. Date: Jan. 4, 2007

(54) Semiconductor packaging structure

(76) Inventors: Daw-Heng Wong, Malaysia (MY); Shr-Hau Hung, Kaohsiung (TW); Tsung-Kang Ying, Taipei (TW)

Correspondence Address: HARNESS, DICKEY & PIERCE, P.L.C., P.O. BOX 8910, RESTON, VA, 20195, US

(21) Appl. No.: 11/280,198

(22) Filed: Nov. 17, 2005

(30) Foreign Application Priority Data
Jun. 30, 2005 (TW) 094122144

(51) Int. Cl. H01L 23/34

(52) U.S. Cl. 257/706

(57) ABSTRACT

A semiconductor packaging structure includes a baseboard, a semiconductor chip set, a thermal conductor, a package and a heat sink. The thermal conductor is located on the baseboard. The semiconductor chip set is directly mounted onto the thermal conductor. The heat sink is coupled on the thermal conductor. Hence heat energy generated by the semiconductor chip set, when electrically energized, is transferred through the thermal conductor to the heat sink, to perform heat exchange.

This Non-provisional application claims priority under 35 U.S.C. §119(a) on Patent Application No(s). 094122144 filed in Taiwan on Jun. 30, 2005, the entire contents of which are hereby incorporated by reference.

### BACKGROUND OF THE INVENTION

1. Field of Invention

The present invention relates to a semiconductor packaging structure and particularly to a packaging structure to provide high heat dissipation efficiency for light emitting diodes (LEDs).

2. Related Art

Applications of the LEDs that function as a light source for consumer electronic products have been expanded to backlight modules, vehicle lights, projectors and the like in recent years. With growing demands on photometric efficiency, product life span and application modes, development of high illumination and high efficiency power LEDs is an intensely pursuing trend at present. To boost photometric efficiency, the general approach is to increase optoelectric conversion efficiency or LED power. As the input power of the LED chip set increases constantly, the problem caused by heat accumulation of the high power LED becomes more severe. As a result, photometric efficiency and life span of the chip set suffer. On the other hand, the factors affecting the light flux output of a unit area of a LED package includes quantum efficiency, chip set dimension (light emission area), input power and heat dissipation capability of the package. To maintain a stable photometric efficiency for the chip set, the heat generated from the light emission area has to be dispersed outside the package quickly. If the package cannot dissipate the heat, conductive wires could be ruptured or packaging plastic material could be deteriorated due to different expansion coefficients of the composing materials of the package, and the reliability is at risk. Moreover, the photometric efficiency of the chip drops significantly as the temperature increases. The life span is shortened, and the wavelength and forward voltage (Vf) tend to fluctuate.

To overcome the heat dissipation problem of high power LEDs, U.S. Pat. No. 6,274,924 (case 924 in short) discloses a surface mountable LED package. In the case 924, a chip set is directly bonded to a radiation pad to channel heat to an external heat-sinking slug located beneath the chip set, to disperse heat. Its package is formed by assembling and bonding to the heat-sinking slug. This approach changes the original packaging process. Moreover, the heat-sinking slug is located beneath the chip set. When adopted on products in actual practice (such as vehicle lights), its position on the circuit board of the vehicle lights has to fit the space configuration or the actual space available on the product to be installed. However, in actual applications, the space on the lower side of the product often is limited, and no adequate heat exchange medium (air) can be provided. Hence heat dissipation efficiency also is limited. Case 924, which adopts the design of bonding the heat-sinking slug to the lower side of the chip set, still has many problems in actual applications.

### SUMMARY OF THE INVENTION

Heat dissipation of high power LEDs is the most important issue in terms of increasing the photometric efficiency and product life span, and the conventional design of bonding a heat-sinking slug to a lower side of the chip, set to perform heat exchange, has many problems, such as altering the packaging process, space constraint and poorer heat dissipation efficiency. Therefore, the present invention aims to provide a high power optoelectric semiconductor packaging structure that has higher heat dissipation efficiency. The semiconductor packaging structure according to the invention includes a baseboard, at least one semiconductor chip set, at least two conductive leads, at least two conductive blades, a thermal conductor, a package and a heat sink. The thermal conductor is located on the baseboard. The semiconductor chip set is directly mounted onto the thermal conductor. The conductive leads are electrically connected to the conductive blades. The package encases the semiconductor chip set. The heat sink is coupled on the thermal conductor. Hence heat energy generated by the semiconductor chip set, when electrically energized, is transferred through the thermal conductor to the heat sink, to perform heat exchange.

According to the semiconductor packaging structure of the invention, the semiconductor chip set is directly mounted onto the thermal conductor on the baseboard. The heat sink is bonded to the thermal conductor to perform heat exchange. As the heat sink is located on the upper side of the baseboard, when adopted and installed on products, it has less space constraint. And heat exchange can be performed more effectively on the upper side of the baseboard to improve heat dissipation efficiency. Such a semiconductor package structure is an optimal design.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given in the illustration below only, and thus is not limitative of the present invention, wherein:

FIG. 1 is an exploded view of a first embodiment of the invention;

FIG. 2 is a perspective view of the first embodiment of the invention;

FIG. 3 is a sectional view of the first embodiment of the invention;

FIGS. 4A and 4B are schematic views of a second embodiment of the invention; and

FIG. 5 is a sectional view of a third embodiment of the invention.

### DETAILED DESCRIPTION OF THE INVENTION

The semiconductor packaging structure according to the invention is adopted for use on optoelectric semiconductors such as LEDs, laser diodes (LDs) and the like. The following embodiments are based on the LEDs.

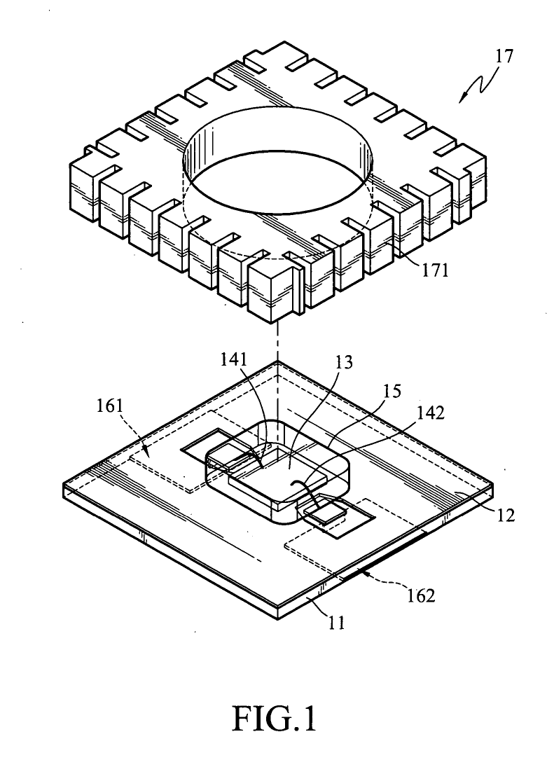

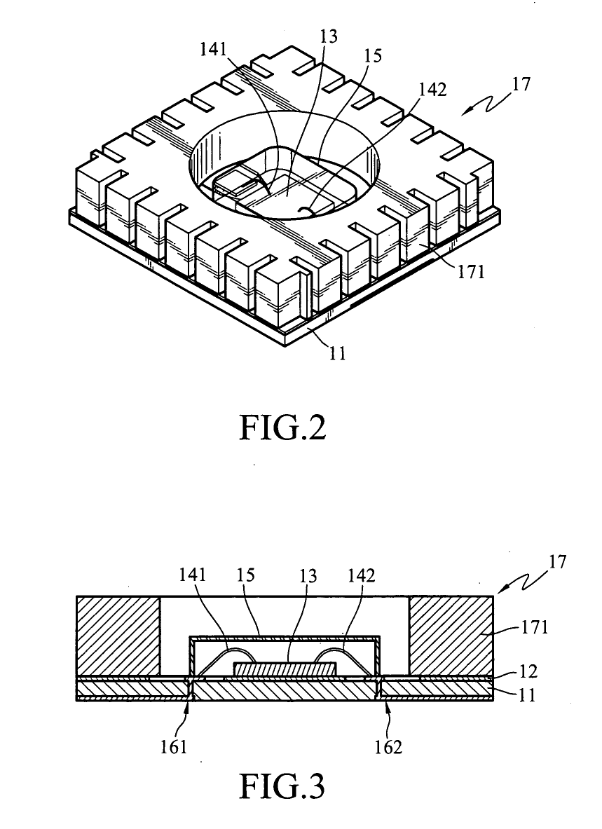

Referring to FIGS. 1, 2 and 3, the semiconductor packaging structure according to the invention includes a baseboard 11, a thermal conductor 12, at least one semiconductor chip set 13, at least two conductive leads 141 and 142, a package 15, at least two conductive blades 161 and 162, and a heat sink 17. The thermal conductor 12 is located on the baseboard 11 and made of a material of a high heat transfer coefficient such as copper or the like. The semiconductor chip set 13 is directly mounted onto the thermal conductor 12 in the center. The conductive leads 141 and 142 have respectively one end electrically connected to two sides of the semiconductor chip set 13 and the other end electrically connected to the two conductive blades 161 and 162 located beneath the baseboard 11. The package 15 encases the semiconductor chip set 13. The heat sink 17 is coupled on the thermal conductor 12 by means of a eutectic process, soldering or high conductivity adhesion. The heat sink 17 may have radiation fins 171 of different shapes and quantity according to the heat dissipation requirement.

After the semiconductor chip set 13 is energized electrically through the conductive blades 161 and 162, and conductive leads 141 and 142, the heat energy it generated during operation is transferred through the thermal conductor 12 to the heat sink 17 to perform heat exchange. As the heat sink 17 is located above the baseboard 11, there is less restriction on space configuration. Moreover, the heat energy generated by the semiconductor chip set 13 can be dispersed more effectively. When used on the optoelectric semiconductors such as LEDs, a higher photometric efficiency can be achieved. Further, deterioration of the package 15 due to high temperature can be prevented, and product life span increases.

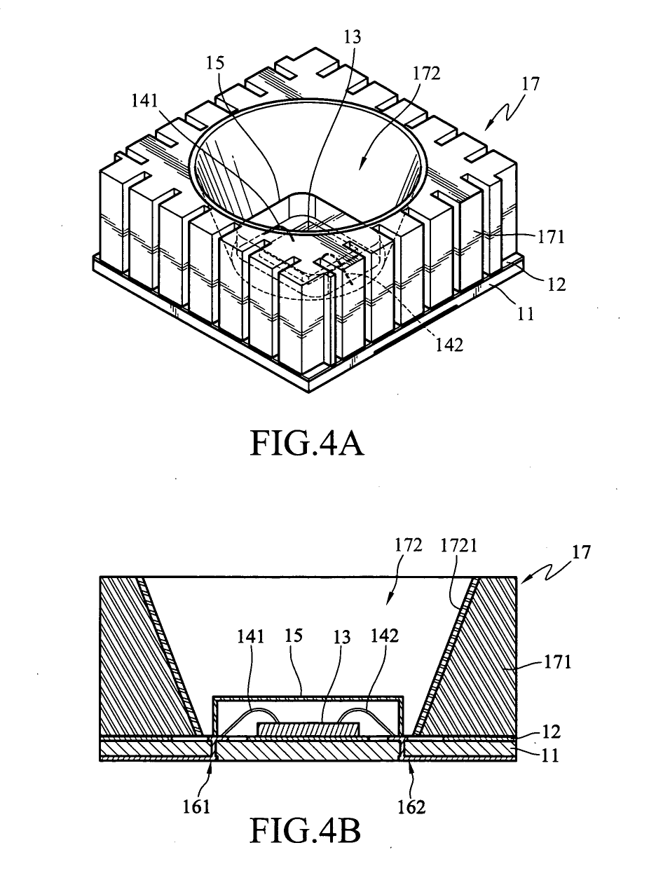

Refer to FIGS. 4A and 4B for a second embodiment of the invention. The heat sink 17 has a conical surface corresponding to the semiconductor chip set 13 to form a reflective portion 172. The surface of the reflective portion 172 may form a reflective layer 1721 by coating or bonding. The curvature of the reflective portion 172 varies according to the light emission requirement, so that light generated by the semiconductor chip set 13 can be converged or scattered via the reflective portion 172.

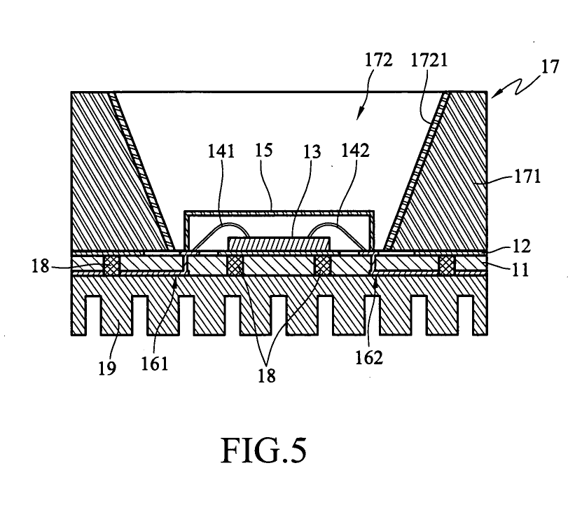

Refer to FIG. 5 for a third embodiment of the invention. The baseboard 11 has a plurality of thermal conductive struts 18 running through the baseboard 11 to connect to the thermal conductor 12. There is a second sink slug 19 below the baseboard 11 to increase radiation area according to the heat dissipation requirement and increase heat dissipation efficiency.

Knowing the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A semiconductor packaging structure, comprising:
a baseboard;
a thermal conductor located on the baseboard;
at least one semiconductor chip set mounted onto the thermal conductor;
a plurality of conductive blades located on the bottom of the baseboard connecting electrically to the semiconductor chip set through a plurality of conductive leads; a package encasing the semiconductor chip set; and
a heat sink coupling with the thermal conductor to perform heat exchange for heat energy generated by the semiconductor chip set and transferred through the thermal conductor.

2. The semiconductor packaging structure of claim 1, wherein the semiconductor chip set is a light emitting diode.

3. The semiconductor packaging structure of claim 1, wherein the semiconductor chip set is a laser diode.

4. The semiconductor packaging structure of claim 1, wherein the heat sink has a reflective portion corresponding to the semiconductor chip set.

5. The semiconductor packaging structure of claim 4, wherein the reflective portion has a reflective layer on the surface thereof.

6. The semiconductor packaging structure of claim 1 further having a plurality of thermal conductive struts running through the baseboard to couple with at least one second heat sink on a lower side thereof.

7. An optoelectric semiconductor packaging structure, comprising:
a baseboard;
a thermal conductor located on the baseboard;
at least one optoelectric semiconductor chip set mounted onto the thermal conductor;
a plurality of conductive blades located on the bottom of the baseboard connecting electrically to the semiconductor chip set through a plurality of conductive leads;
a package encasing the optoelectric semiconductor chip set; and
a heat sink coupling with the thermal conductor and having a reflective portion corresponding to the optoelectric semiconductor chip set to perform heat exchange for heat energy generated by the optoelectric semiconductor chip set and transferred through the thermal conductor, light generated by the optoelectric semiconductor chip set being projected outwards by the reflective portion.

8. The semiconductor packaging structure of claim 7, wherein the optoelectric semiconductor chip set is a light emitting diode.

9. The semiconductor packaging structure of claim 7, wherein the optoelectric semiconductor chip set is a laser diode.

10. The semiconductor packaging structure of claim 7, wherein the reflective portion has a reflective layer on the surface thereof.

11. The semiconductor packaging structure of claim 7 further having a plurality of thermal conductive struts running through the baseboard to couple at least one second heat sink on a lower side thereof.
